(19) United States
(12) Patent Application Publication
(10) Pub. No.: US 2022/0091779 A1
(43) Pub. Date: Mar. 24, 2022

(54) MEMORY SYSTEM AND OPERATING METHOD OF THE MEMORY SYSTEM

(71) Applicant: SK hynix Inc., Icheon-si Gyeonggi-do (KR)

(72) Inventor: Jong Wook KIM, Icheon-si Gyeonggi-do (KR)

(73) Assignee: SK hynix Inc., Icheon-si Gyeonggi-do (KR)

(21) Appl. No.: 17/209,868

(22) Filed: Mar. 23, 2021

(30) Foreign Application Priority Data
Sep. 22, 2020 (KR) 10-2020-0122216

(51) Int. Cl. G06F 3/06; G06F 12/02

(52) U.S. Cl. CPC G06F 3/0655; G06F 12/0253; G06F 2212/7205; G06F 3/0679; G06F 3/0604

(57) ABSTRACT

A memory system, and an operating method of the memory system, includes a memory device including a plurality of semiconductor memories. The memory system also includes a controller for setting a performance period of a garbage collection operation of each of the plurality of semiconductor memories, based on a mobile ion amount of each of the plurality of semiconductor memories, and controlling the garbage collection operation of the plurality of semiconductor memories, based on the set performance period.

### CROSS-REFERENCE TO RELATED APPLICATION

The present application claims priority under 35 U.S.C. § 119(a) to Korean patent application number 10-2020-0122216, filed on Sep. 22, 2020, in the Korean Intellectual Property Office, the entire disclosure of which is incorporated herein by reference.

### BACKGROUND

### 1. Technical Field

The present disclosure generally relates to an electronic device, and more particularly, to a memory system and an operating method of the memory system.

### 2. Related Art

The paradigm for computing has evolved into ubiquitous computing in which computing systems are accessible anywhere and anytime. This promotes increasing usage of portable electronic devices such as mobile phones, digital cameras, notebook computers, and the like. Such portable electronic devices may generally include a memory system using a memory device, i.e., a data storage device. The data storage device is used as a main memory device or an auxiliary memory device of a portable electronic device.

A data storage device using a memory device has excellent stability and durability, high information access speed, and low power consumption, because there are no mechanically driven parts. In examples of memory systems having such advantages, the data storage device includes a Universal Serial Bus (USB) memory device, memory cards having various interfaces, a Solid State Drive (SSD), and the like.

A memory device is generally classified as a volatile memory device or a nonvolatile memory device.

A nonvolatile memory device has relatively slow write and read speeds, but retains stored data even when a supply of power is interrupted. Thus, the nonvolatile memory device is used to store data to be retained regardless of whether power is supplied.

Examples of volatile memory include Read Only Memory (ROM), Mask ROM (MROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), Ferroelectric RAM (FRAM), and the like. Flash memory is classified as NOR-type flash memory or NAND-type flash memory.

### SUMMARY

Embodiments are directed to a memory system for performing a garbage collection operation according to a retention characteristic of each semiconductor memory included in a memory device, and an operating method of the memory system.

In accordance with an embodiment of the present disclosure, a memory system includes a memory device including a plurality of semiconductor memories. The memory system also includes a controller configured to set a performance period of a garbage collection operation of each of the plurality of semiconductor memories, based on a mobile ion amount of each of the plurality of semiconductor memories, and control the garbage collection operation of the plurality of semiconductor memories, based on the set performance period.

In accordance with another embodiment of the present disclosure, a method for operating a memory system includes: providing a memory device including a plurality of semiconductor memories and providing a controller for controlling the memory device; performing a program operation on each of the plurality of semiconductor memories; performing a read operation on each of the plurality of semiconductor memories after the program operation is completed; detecting and counting fail bits, based on a result of the read operation; measuring a mobile ion amount of each of the plurality of semiconductor memories, based on the counted number of fail bits; and storing information on the mobile ion amount of each of the plurality of semiconductor memories in a Content Addressable Memory (CAM) block of each of the plurality of semiconductor memories or the controller.

In accordance with still another embodiment of the present disclosure, a method for operating a memory system includes: reading a mobile ion amount stored in a Content Addressable Memory (CAM) block included in each of a plurality of semiconductor memories and storing the read mobile ion amount in a garbage collection controller of a controller; setting a performance period of a garbage collection operation of each of the plurality of semiconductor memories, based on the mobile ion amount of each of the plurality of semiconductor memories, which is stored in the garbage collection controller; and performing the garbage collection operation of a semiconductor memory which reaches the performance period of the garbage collection operation among the plurality of semiconductor memories.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a memory system in accordance with an embodiment of the present disclosure.

FIG. 2 is a block diagram illustrating a configuration of a controller shown in FIG. 1.

FIG. 3 is a block diagram illustrating semiconductor memory shown in FIG. 1.

FIG. 4 is a block diagram illustrating an embodiment of a memory cell array shown in FIG. 3.

FIG. 5 is a circuit diagram illustrating a memory block shown in FIG. 4.

FIG. 6 is a flowchart illustrating a method for measuring a mobile ion amount in accordance with a first embodiment of the present disclosure.

FIG. 7 is a threshold voltage distribution diagram illustrating a threshold voltage distribution of memory cells.

FIG. 8 is a flowchart illustrating a method for measuring a mobile ion amount in accordance with a second embodiment of the present disclosure.

FIG. 9 is a diagram illustrating a garbage collection operation.

FIG. 10 is a diagram illustrating another embodiment of a memory system in accordance with an embodiment of the present disclosure.

FIG. 11 is a diagram illustrating another embodiment of a memory system in accordance with an embodiment of the present disclosure.

FIG. 12 is a diagram illustrating another embodiment of a memory system in accordance with an embodiment of the present disclosure.

FIG. 13 is a diagram illustrating another embodiment of a memory system in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and should not be construed as limited to the embodiments set forth herein.

Hereinafter, embodiments of the present disclosure will be described in detail with reference to the accompanying drawings in order for those skilled in the art to be able to readily implement the technical spirit of the present disclosure.

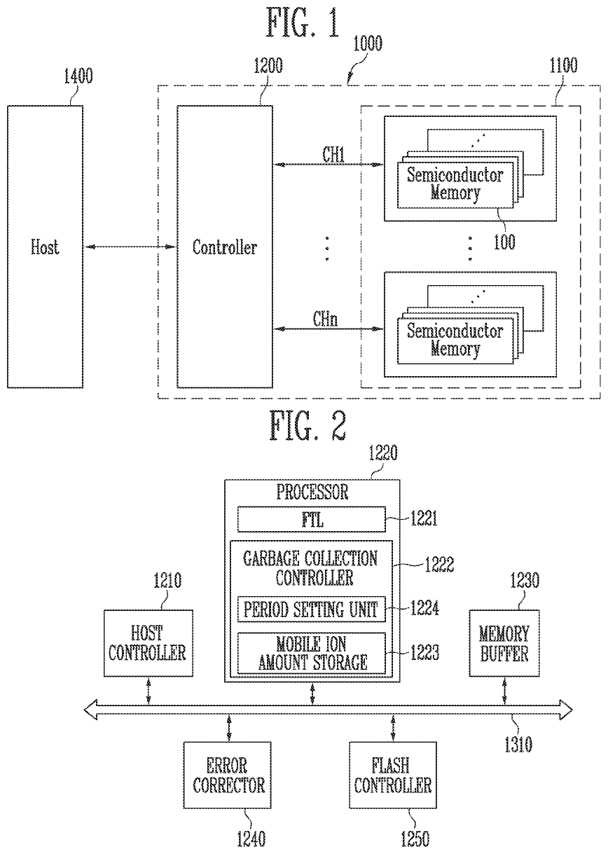

FIG. 1 is a block diagram illustrating a memory system 1000 in accordance with an embodiment of the present disclosure.

Referring to FIG. 1, the memory system 1000 includes a memory device 1100 and a controller 1200.

The memory device 1100 includes a plurality of semiconductor memories 100. The plurality of semiconductor memories 100 may be divided into a plurality of groups.

The plurality of semiconductor memories 100 may include a plurality of memory blocks capable of storing data, and use at least one memory block among the plurality of memory blocks as a Content Addressable Memory (CAM) block. In an embodiment, the CAM block may store data about a mobile ion amount of a corresponding semiconductor memory.

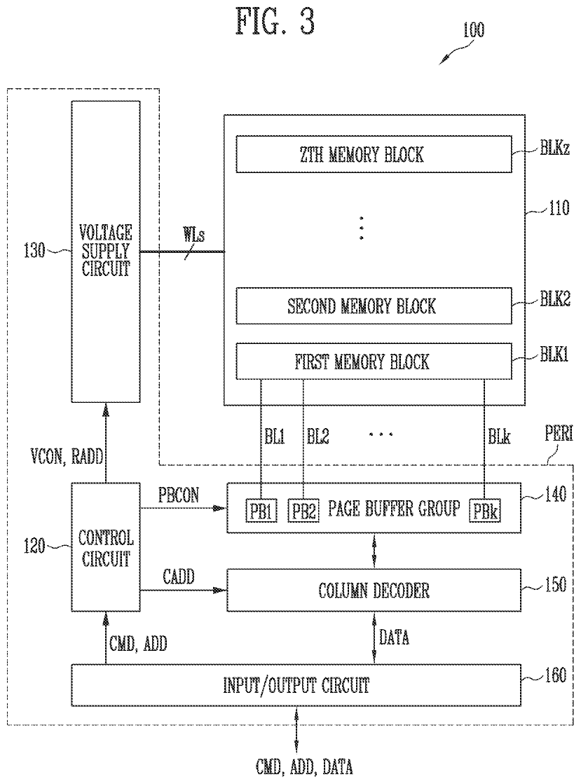

In FIG. 1, it is illustrated that the plurality of groups communicate with the controller 1200 respectively through first to nth channels CH1 to CHn is illustrated. Each semiconductor memory 100 will be described later with reference to FIG. 3.

Each group communicates with the controller 1200 through one common channel. The controller 1200 controls the plurality of semiconductor memories 100 of the memory device 100 through the plurality of channels CH1 to CHn.

The controller 1200 is coupled between a host 1400 and the memory device 1100. The controller 1200 accesses the memory device 1100 in response to a request from the host 1400. For example, the controller 1200 controls read, write, erase, and background operations of the memory device 1100 in response to a request received from the host 1400. The controller 1200 provides an interface between the memory device 1100 and the host 1400. The controller 1200 drives firmware for controlling the memory device 1100. Also, the controller 1200 sets a performance period of a Garbage Collection (GC) operation on each of the plurality of semiconductor memories 100 constituting the memory device 1100, and controls the GC operation of each of the plurality of semiconductor memories 100, based on the performance period. The GC operation is an operation of selecting at least one victim block storing valid data among a plurality of memory blocks included in a semiconductor memory, copying only valid data among data stored in the victim block, storing the copied valid data in a target block in an erase state among the plurality of memory blocks, and then erasing the selected victim block.

In an embodiment, the controller 1200 stores data about a mobile ion amount of each of the plurality of semiconductor memories 100. The controller 1200 sets a performance period of the GC operation of each of the plurality of semiconductor memories 100, based on the mobile ion amount of each of the plurality of semiconductor memories 100. The controller 1200 controls the GC operation of each of the plurality of semiconductor memories 100, based on the set performance period. In another embodiment, the controller 1200 receives data about a mobile ion amount stored in each of the plurality of semiconductor memories 100. The controller 1200 sets a performance period of a GC operation of each of the plurality of semiconductor memories, based on the received data about the mobile ion amount of each of the plurality of semiconductor memories 100. The controller 1200 controls the GC operation of each of the plurality of semiconductor memories 100, based on the set performance period.

The memory system 1000 may be designed to additionally include a buffer memory.

The host 1400 controls the memory system 1000. The host 1400 includes portable electronic devices such as a computer, a PDA, a PMP, an MP3 player, a camera, a camcorder, and a mobile phone. The host 1400 may request a write operation, a read operation, an erase operation, etc. of the memory system 1000 through a command.

The controller 1200 and the memory device 1100 may be integrated into one semiconductor device. In an embodiment, the controller 1200 and the memory device 1100 may be integrated into one semiconductor device, to constitute a memory card. For example, the controller 1200 and the memory device 1100 may be integrated into one semiconductor device, to constitute a memory card such as a PC card (Personal Computer Memory Card International Association (PCMCIA)), a Compact Flash (CF) card, a Smart Media Card (SM or SMC), a memory stick, a Multi-Media Card (MMC, RS-MMC or MMCmicro), an SD card (SD, miniSD, microSD or SDHC), or a Universal Flash Storage (UFS).

The controller 1200 and the memory device 1100 may be integrated into one semiconductor device to constitute a semiconductor drive (Solid State Drive (SSD)). The semiconductor drive SSD includes a storage device configured to store data in a semiconductor memory. When the memory system 1000 is used as the semiconductor drive (SDD), the operating speed of the host 1400 coupled to the memory system 1000 is remarkably improved.

In another example, the memory system 1000 may be provided as one of various components of an electronic device such as a computer, an Ultra Mobile PC (UMPC), a workstation, a net-book, a Personal Digital Assistant (PDA), a portable computer, a web tablet, a wireless phone, a mobile phone, a smart phone, an e-book, a Portable Multi-Media Player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an exemplary embodiment, the memory device 1100 or the memory system 1000 may be packaged in various forms. For example, the memory device 1100 or the memory system 1000 may be packaged in a manner such as Package On Package (PoP), Ball Grid Arrays (BGAs), Chip Scale Packages (CSPs), Plastic Leaded Chip Carrier (PLCC), Plastic Dual In-line Package (PDIP), die in Waffle pack, die in wafer form, Chip On Board (COB), CERamic Dual In-line Package (CERDIP), Plastic Metric Quad Flat Pack (PMQFP), Thin Quad Flat Pack (TQFP), Small Outline Integrated Circuit (SOIC), Shrink Small Outline Package (SSOP), Thin Small Outline Package (TSOP), System In Package (SIP), Multi-Chip Package (MCP), Wafer-level Fabricated Package (WFP), or Wafer-level processed Stack Package (WSP).

FIG. 2 is a block diagram illustrating a configuration of the controller shown in FIG. 1.

Referring to FIG. 2, the controller 1200 may include a host controller 1210, a processor 1220, a memory buffer 1230, an error corrector 1240, a flash controller 1250, and a bus 1310.

The bus 1310 may provide a channel between components of the controller 1200.

The host controller 1210 may control data transmission between the host 1400 shown in FIG. 1 and the memory buffer 1230. In an example, the host controller 1210 may control an operation of buffering data input from the host 1400 to the memory buffer 1230. In another example, the host controller 1210 may control an operation of outputting, to the host 1400, the data buffered to the memory buffer 1230. The host controller 1210 may include a host interface.

The processor 1220 may include a Flash Translation Layer (FTL) (hereinafter, referred to as an ‘FTL’) and a garbage collection controller 1222.

The FTL 1221 drives firmware stored in the memory buffer 1230. Also, the FTL 1221 may map a corresponding physical address to a logical address input from the host 1400 shown in FIG. 1 in a data write operation. Also, the FTL 1221 checks the physical address mapped to the logical address input from the host 1400 in a data read operation.

The garbage collection controller 1222 stores data about a mobile ion amount of each of the plurality of semiconductor memories 100 shown in FIG. 1, and sets a performance period of a garbage collection operation of each of the plurality of semiconductor memories 100, based on the stored data about the mobile ion amount. Also, the garbage collection controller 1222 may control the semiconductor memories 100 to each perform the garbage collection operation.

The garbage collection controller 1222 may include a mobile ion amount storage 1223 and a period setting unit 1224.

The mobile ion amount storage 1223 stores data about a mobile ion amount of each of the plurality of semiconductor memories 100. In an embodiment, the mobile ion amount storage 1223 may store data about a mobile ion amount measured by a mobile ion amount measuring operation performed in a test operation at a wafer level or packaging level of the memory device 1100 shown in FIG. 1. In another embodiment, the data about the mobile ion amount measured by the mobile ion amount measuring operation performed in the test operation at the wafer level or packaging level of the memory device 1100 is stored in a CAM block of each of the semiconductor memories 100. The data about the mobile ion amount, which is stored in the CAM block of each of the semiconductor memories 100, is read in a booting operation of the memory system 1000. The read data about the mobile ion amount of each of the semiconductor memories 100 may be stored in the mobile ion amount storage 1223.

The period setting unit 1224 sets a performance period of the garbage collection of each of the plurality of semiconductor memories 100, based on the data about the mobile ion amount of each of the plurality of semiconductor memories 100, which is stored in the mobile ion amount storage 1223.

The memory buffer 1230 may be used as a working memory, cache memory, or buffer memory of the processor 1220. The memory buffer 1230 may store codes and commands, which are executed by the processor 1220. The memory buffer 1230 may store data processed by the processor 1220. The memory buffer 1230 may include Static RAM (SRAM) or Dynamic RAM (DRAM). The memory buffer 1230 may store a command queue generated by the processor 1220.

The error corrector 1240 may perform error correction. The error corrector 1240 may perform Error Correction Code (ECC) encoding, based on data to be written to the memory device 1100 shown in FIG. 1 through the flash controller 1250. The ECC-encoded data may be transferred to the memory device 1100 through the flash controller 1250. The error corrector 1240 may perform ECC decoding on data received from the memory device 1100 through the flash controller 1250. In an example, the error corrector 1240 may be included in the flash controller 1250 as a component of the flash controller 1250.

In an embodiment, when fail occurs as the result of an ECC decoding operation performed by the error corrector 1240 in a read operation, the processor 1220 may control the memory device 1100 shown in FIG. 1 to perform a defense algorithm operation. A defense algorithm re-performs a read operation of adjusting a read voltage, such as a read retry operation, an eBoost operation, or a soft decoding operation, and decrease an error occurrence rate in the read operation.

The flash controller 1250 generates and outputs an internal command for controlling the memory device 1100 in response to a command queue generated by the processor 1220. The flash controller 1250 may control a program operation by transmitting data buffered to the memory buffer 1230 to the memory device 1100 in a data write operation. In another example, the flash controller 1250 may control an operation of buffering data read and output from the memory device 1100 to the memory buffer 1230 in response to the command queue in a read operation. The flash controller 1250 may include a flash interface.

FIG. 3 is a block diagram illustrating the semiconductor memory 100 shown in FIG. 1.

Referring to FIG. 3, the semiconductor memory 100 includes a memory cell array 110 including a plurality of memory blocks BLK1 to BLKz, and a peripheral circuit PERI configured to perform a program operation, a read operation, or an erase operation of memory cells included in a selected page of the plurality of memory blocks BLK1 to BLKz. The peripheral circuit PERI includes a control circuit 120, a voltage supply circuit 130, a page buffer group 140, a column decoder 150, and an input/output circuit 160.

The peripheral circuit PERI may be disposed in a lower region of the memory cell array 110. For example, the peripheral circuit PERI may be formed on a substrate, and the memory cell array 110 may be formed on the peripheral circuit PERI. The peripheral circuit PERI and the memory cell array 110 are coupled to each other through word lines WLs. The word lines WLs are formed through a conductive contact forming process. Mobile ions are generated in the contact forming process, and therefore, retention characteristics of memory cells included in the memory cell array 110 may be deteriorated.

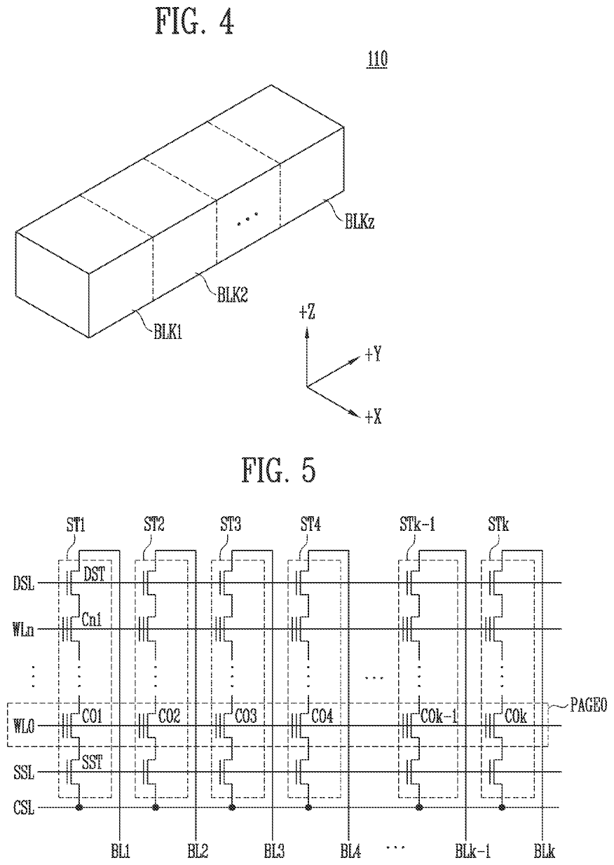

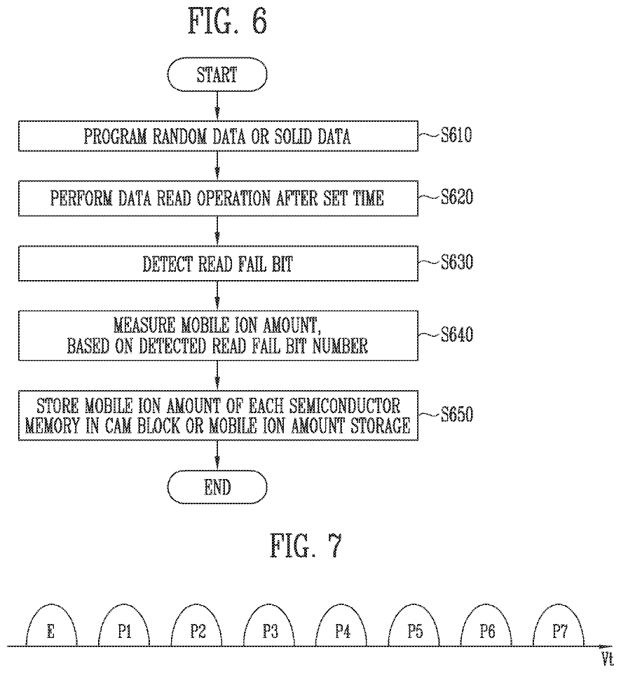

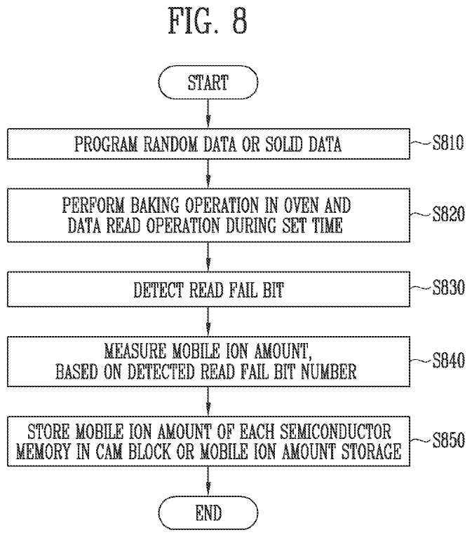

The memory cell array 110 includes the plurality of memory blocks BLK1 to BLKz. Each of the plurality of memory blocks BLK1 to BLKz includes a plurality of pages. Each of the plurality of pages includes a plurality of memory cells. In an embodiment, the plurality of memory cells are nonvolatile memory cells. This will be described in more detail with reference to FIGS. 4 and 5. In an embodiment, at least one memory block BLK1 among the plurality of memory blocks BLK1 to BLKz may be used as a CAM block. The CAM block may store data about a mobile ion amount of the semiconductor memory 100. The data about the mobile ion amount is data based on the result of a test operation performed at a wafer level or packaging level of the semiconductor memory 100, i.e., a mobile ion amount measuring operation. The mobile ion amount measuring operation will be described later with reference to FIG. 6 or 8.

The control circuit 120 outputs a voltage control signal VCON for generating a voltage required to perform a read operation, a program operation, or an erase operation in response to a command CMD input from the outside of the peripheral circuit PERI through the input/output circuit 160, and outputs a page buffer (PB) control signal PBCON for controlling page buffers PB1 to PBk included in the page buffer group 140 according to a kind of operation. Also, the control circuit 120 outputs a row address signal RADD and a column address signal CADD in response to an address signal ADD input from the outside of the peripheral circuit PERI through the input/output circuit 160.

The control circuit 120 controls the peripheral circuit PERI to program valid data stored in a selected memory block, i.e., a victim block among a plurality of memory blocks to a memory block in an erase state, i.e., a target block in a garbage collection operation. The control circuit 120 controls the peripheral circuit PERI to erase the victim block when a program operation of the target block is completed. More specifically, the control circuit 120 controls the peripheral circuit PERI to read the valid data stored in the victim block and transmit the read valid data to the controller 1200 shown in FIG. 1 in the garbage collection operation. The control circuit 120 controls the peripheral circuit PERI to receive valid data from the controller 1200 and to program the received valid data to the target block. The valid data received from the controller 1200 may be data on which an error correction operation is performed by the error corrector 1240 shown in FIG. 2. The control circuit 120 controls the peripheral circuit PERI to erase the victim block, during the program operation of the target block or after the program operation is completed.

The voltage supply circuit 130 supplies operating voltages necessary for a program operation, a read operation, and an erase operation of memory cells to local lines including a drain select line, word lines WLs, and a source select line of the selected memory block in response to the voltage control signal VCON of the control circuit 120. The voltage supply circuit 130 includes a voltage generating circuit and a row decoder.

The voltage generating circuit 120 outputs, to global lines, operating voltages necessary for a program operation, a read operation, and an erase operation of memory cells, in response to the voltage control signal VCON.

The row decoder couples the global lines and the local lines to each other such that the operating voltages output to the global lines from the voltage generating circuit are transferred to local lines of the selected memory block of the memory cell array 110, in response to the row address signal RADD of the control circuit 120.

The page buffer group 140 includes a plurality of page buffers PB1 to PBk coupled to the memory cell array 110 respectively through bit lines BL1 to BLk. The page buffers PB1 to PBk of the page buffer group 140 selectively precharge the bit lines BL1 to BLk according to data DATA input to be stored in memory cells or sense a voltage or current amount of the bit lines BL1 to BLk to read data DATA from the memory cells, in response to the PB control signal PBCON.

The column decoder 150 selects the page buffers PB1 to PBk included in the page buffer group 140 in response to the column address signal CADD output from the control circuit 120. That is, the column decoder 150 transfers data DATA to be stored in memory cells sequentially to the page buffers PB1 to PBk in response to the column address signal CADD. Also, the column decoder 150 sequentially selects the page buffers PB1 to PBk in response to the column address signal CADD such that the data DATA of the memory cells, which are latched to the page buffers PB1 to PBk can be output to the outside of the peripheral circuit PERI through a read operation.

The input/output circuit 160 transfers data DATA Input to be stored in memory cells in a program operation to the column decoder 150 so as to input the data DATA to the page buffer group 140 under the control of the control logic 120. When the column decoder 150 transfers the data DATA transferred from the input/output circuit 160 to the page buffers PB1 to PBk of the page buffer group 140, the page buffers PB1 to PBk store the input data DATA to a latch circuit provided therein. Also, the input/output circuit 160 outputs, to the outside, the data DATA transferred from the page buffers PB1 to PBk of the page buffer group 140 through the column decoder 150 in a read operation.

FIG. 4 is a block diagram illustrating an embodiment of the memory cell array 110 shown in FIG. 3.

Referring to FIG. 4, the memory cell array 110 includes a plurality of memory blocks BLK1 to BLKz. Each memory block has a three-dimensional structure. Each memory block includes a plurality of memory cells stacked on a substrate. The plurality of memory cells may be arranged along +X, +Y, and +Z directions. A structure of each memory block will be described in more detail with reference to FIG. 5.

FIG. 5 is a circuit diagram illustrating a memory block shown in FIG. 4.

Referring to FIG. 5, each memory block includes a plurality of strings ST1 to STk coupled between bit lines BL1 to BLk and a common source line CSL. That is, the strings ST1 to STk are respectively coupled to corresponding bit lines BL1 to BLk, and are commonly coupled to the common source line CSL. Each string ST1 includes a source select transistor SST having a source coupled to the common source line CSL, a plurality of memory cells C01 to Cn1, and a drain select transistor DST having a drain coupled to a bit line BL1. The memory cells C01 to Cn1 are coupled in series between the select transistors SST and DST. A gate of the source select transistor SST is coupled to a source select line SSL, gates of the memory cells C01 to Cn1 are respectively coupled to word lines WL0 to WLn, and a gate of the drain select transistor DST is coupled to a drain select line DSL.

The memory cells included in the memory block may be divided into physical page units or a logical page units. For example, memory cells C01 to C0k coupled to one word line (e.g., WL0) constitutes one physical page PAGE0.

FIG. 6 is a flowchart illustrating a method for measuring a mobile ion amount in accordance with a first embodiment of the present disclosure.

FIG. 7 is a threshold voltage distribution diagram illustrating a threshold voltage distribution of memory cells.

The method for measuring a mobile ion amount in accordance with the first embodiment of the present disclosure will be described as follows with reference to FIGS. 1 to 7.

A measuring operation of measuring a mobile ion amount may be performed at a wafer level at which the semiconductor memories 100 included in the memory device 100 shown in FIG. 1 are in a wafer state or at a packaging level at which the memory device 1100 including the plurality of semiconductor memories 100 and the controller 1200 are packaged.

In step S610, each of the semiconductor memories 100 programs random data or solid data by selecting at least one memory block or all the memory blocks among the plurality of memory blocks BLK1 to BLKz. The operation of programming the random data or the solid data may be defined as a test program operation. The random data may be data in which data respectively corresponding to an erase state E and a plurality of program states P1 to P7 are equally included as shown in FIG. 7. The solid data may be data in which only data corresponding to one set program state (e.g., P1) among the plurality of program states P1 to P7 is included.

For example, the page buffer group 140 of the semiconductor memory 100 receives and arbitrarily stores random data or solid data to be programmed from the outside of the peripheral circuit PERI and adjusts a potential level of the bit lines BL1 to BLk, based on the temporarily stored data, in response to the PB control signal PBCON of the control circuit 120.

The voltage supply circuit 130 supplies operating voltages necessary for a program operation of memory cells to local lines including a drain select line, word lines WLs, and a source select line of a selected memory block in response to the voltage control signal VCON, thereby performing the program operation.

In step S620, after a set time from when the program operation is completed in the step S610, each of the semiconductor memories 100 performs a data read operation by selecting at least one memory block or all the memory blocks, to which the random data or the solid data is programmed. This may be defined as a test read operation.

For example, the voltage supply circuit 130 of the semiconductor memory 100 supplies operating voltages necessary for a read operation of memory cells to the local lines including the drain select line, the word lines WLs, and the source select line of the selected memory block in response to the voltage control signal VCON.

The page buffer group 140 latches read data by sensing a voltage or current amount of the bit lines BL1 to BLk of the selected memory block in response to the PB control signal PBCON of the control circuit 120.

The read data latched by the page buffer group 140 may be output to the outside of the peripheral circuit PERI through the column decoder 150 and the input/output circuit 160.

In step S630, a read fail bit of each of the plurality of semiconductor memories 100 is detected. The read fail bit may be detected by comparing the random data programmed in the step S610 and the data read in the step S620 with each other and detecting a number of different data. For example, when the solid data is programmed in the step S610, the read fail bit may be detected by counting data except the solid data among the data read in the step S620.

In step S640, a mobile ion amount of each of the plurality of semiconductor memories 100 is measured based on the detected read fail bit number. For example, a mobile ion amount corresponding to the read fail bit number of each semiconductor memory 100 is measured as the mobile ion amount of each semiconductor memory 100. For example, as the read fail bit number becomes larger, the corresponding mobile ion amount increases. As the read fail bit number becomes smaller, the corresponding mobile ion amount decreases.

In step S650, data about the mobile ion amount of each semiconductor memory 100 is stored in the CAM block (e.g., BLK1) of each semiconductor memory 100 or the mobile ion amount storage 1223 of the controller 1200.

FIG. 8 is a flowchart illustrating a method for measuring a mobile ion amount in accordance with a second embodiment of the present disclosure.

The method for measuring a mobile ion amount in accordance with the second embodiment of the present disclosure will be described as follows with reference to FIGS. 1 to 5, 7, and 8.

A measuring operation of measuring a mobile ion amount may be performed at a wafer level at which the semiconductor memories 100 included in the memory device 100 shown in FIG. 1 are in a wafer state or at a packaging level at which the memory device 1100 including the plurality of semiconductor memories 100 and the controller 1200 are packaged.

In step S810, each of the semiconductor memories 100 programs random data or solid data by selecting at least one memory block or all the memory blocks among the plurality of memory blocks BLK1 to BLKz. The operation of programming the random data or the solid data may be defined as a test program operation. The random data may be data in which data respectively corresponding to the erase state E and the plurality of program states P1 to P7 are equally included as shown in FIG. 7. The solid data may be data in which only data corresponding to one set program state (e.g., P1) among the plurality of program states P1 to P7 is included.

For example, the page buffer group 140 of the semiconductor memory 100 receives and arbitrarily stores random data or solid data to be programmed from the outside of the peripheral circuit PERI and adjusts a potential level of the bit lines BL1 to BLk, based on the temporarily stored data, in response to the PB control signal PBCON of the control circuit 120.

The voltage supply circuit 130 supplies operating voltages necessary for a program operation of memory cells to local lines including a drain select line, word lines WLs, and a source select line of a selected memory block in response to the voltage control signal VCON, thereby performing the program operation.

In step S820, during a set time after the program operation is completed in the step S610, a baking operation is performed, in an oven, on a wafer on which the semiconductor memories 100 are formed or a package chip in which the memory device 1100 and the controller 120 are packaged. That is, during the set time, a set temperature is applied to the wafer on which the semiconductor memories 100 are formed or the package chip in which the memory device 1100 and the controller 120 are packaged.

Subsequently, each of the semiconductor memories 100 performs a data read operation by selecting at least one memory block or all the memory blocks, to which the random data or the solid data is programmed. This may be defined as a test read operation.

For example, the voltage supply circuit 130 of the semiconductor memory 100 supplies operating voltages necessary for a read operation of memory cells to the local lines including the drain select line, the word lines WLs, and the source select line of the selected memory block in response to the voltage control signal VCON.

The page buffer group 140 latches read data by sensing a voltage or current amount of the bit lines BL1 to BLk of the selected memory block in response to the PB control signal PBCON of the control circuit 120.

The read data latched by the page buffer group 140 may be output to the outside of the peripheral circuit PERI through the column decoder 150 and the input/output circuit 160.

In step S830, a read fail bit of each of the plurality of semiconductor memories 100 is detected. The read fail bit may be detected by comparing the random data programmed in the step S810 and the data read in the step S820 with each other and detecting a number of different data. For example, when the solid data is programmed in the step S810, the read fail bit may be detected by counting data except the solid data among the data read in the step S820.

In step S840, a mobile ion amount of each of the plurality of semiconductor memories 100 is measured based on the detected read fail bit number. For example, a mobile ion amount corresponding to the read fail bit number of each semiconductor memory 100 is measured as the mobile ion amount of each semiconductor memory 100. For example, as the read fail bit number becomes larger, the corresponding mobile ion amount increases. As the read fail bit number becomes smaller, the corresponding mobile ion amount decreases.

In step S850, data about the mobile ion amount of each semiconductor memory 100 is stored in the CAM block (e.g., BLK1) of each semiconductor memory 100 or the mobile ion amount storage 1223 of the controller 1200.

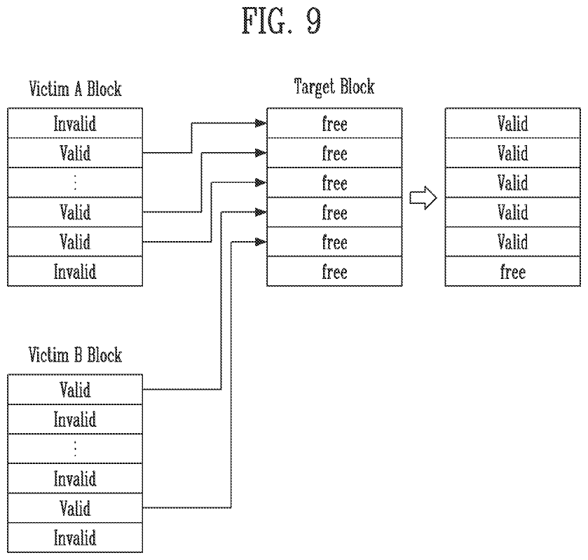

FIG. 9 is a diagram illustrating a garbage collection operation.

The garbage collection operation of the memory system 1000 in accordance with the embodiment of the present disclosure will be described as follows with reference to FIGS. 1, 2, and 9.

The processor 1220 of the controller 1200 manages a performance period of a garbage collection operation of each of the plurality of semiconductor memories 100 included in the memory device 1100.

For example, the period setting unit 1224 of the garbage collection controller 1222 sets a performance period of the garbage collection operation of each of the plurality of semiconductor memories 100, based on data about a mobile ion amount of each of the plurality of semiconductor memories 100, which is stored in the mobile ion amount storage 1223. For example, the period setting unit 1224 may set the performance period of the garbage collection operation to become relatively shorter as a mobile ion amount corresponding to the semiconductor memory 100 becomes larger, and may set the performance period of the garbage collection operation to become relatively longer as a mobile ion amount corresponding to the semiconductor memory 100 becomes smaller.

The mobile ion amount storage 1223 may store the data about the mobile ion amount of each of the plurality of semiconductor memories 100.

In an embodiment, the mobile ion amount storage 1223 may store the data about the mobile ion amount measured using the method for measuring the mobile ion amount in accordance with the first embodiment of the present disclosure or the method for measuring the mobile ion amount in accordance with the second embodiment of the present disclosure, which are described with reference to FIG. 6 or 8.

In another embodiment, a mobile ion amount of each semiconductor memory 100 is measured in the method for measuring the mobile ion amount in accordance with the first embodiment of the present disclosure or the method for measuring the mobile ion amount in accordance with the second embodiment of the present disclosure to be stored a CAM block of each semiconductor memory 100. Data about the mobile ion amount stored in the CAM block of each semiconductor memory 100 is read in a booting operation of the memory system 1000. The read data about the mobile ion amount of each semiconductor memory 100 may be stored in the mobile ion amount storage 1223.

The garbage collection controller 1222 may control the semiconductor memories 100 to perform the garbage collection operation of each of the semiconductor memories 100, based on the set performance period of the garbage collection operation of each of the semiconductor memories 100. For example, the garbage collection controller 1222 checks a time up to the present from a time at which a last garbage collection operation of each of the plurality of semiconductor memories 100 was performed (i.e., a time since a last garbage collection operation of each of the plurality of semiconductor memories was performed), and controls the memory device 1100 to perform the garbage collection operation on a semiconductor memory 100 for which the checked time reaches the performance period of the garbage collection operation.

In an embodiment of the present disclosure, a case where the garbage collection operation is performed by storing, in a target block Target Block, valid data of a victim block A Victim A Block and a victim block B Victim B Block of the semiconductor memory 100 of which the checked time reaches the performance period of the garbage collection operation is described as an example.

Referring to FIG. 9, a plurality of pages included in the victim block A Victim A Block may include pages Valid in which valid data are stored and pages Invalid in which invalid data are stored. In addition, a plurality of pages included in the victim block B Victim B Block may include pages Valid in which valid data are stored and pages Invalid in which invalid data are stored.

The target block Target Block is configured with pages in an erase state free in which no data is stored because the target block Target Block is selected as one of free blocks among memory blocks.

In the garbage collection operation, data of pages Valid in which valid data are stored among the plurality of pages included in the victim block A Victim A Block and the victim block B Victim B Block are read, and the read data are transmitted to the error corrector 1240 shown in FIG. 2. The error corrector 1240 performs an error correction operation on the received data, and the error-corrected data is stored in the memory buffer 1230. Subsequently, the valid data stored in the memory buffer 1230 are stored in the target block Target Block in a page unit. That is, valid data stored in a plurality of victim blocks are copied and stored in a target block. Thus, the valid data stored in the plurality of victim blocks can all be stored in a number of target blocks which is smaller than the number of victim blocks.

The victim block A Victim A Block and the victim block B Victim B of which the valid data are stored in the target block are erased to become free blocks.

As described above, in accordance with an embodiment of the present disclosure, a mobile ion measuring operation is performed on each semiconductor memory at a wafer level or a package level, and a performance period of a garbage collection operation of each semiconductor memory is optimized and set based on a measured mobile ion amount. Accordingly, an error occurrence rate in a read operation can be decreased by the optimized garbage collection operation of the each semiconductor memory. Further, because the error occurrence rate is decreased, a number of times a defense algorithm is performed can be decreased, and characteristics of the read operation can be improved.

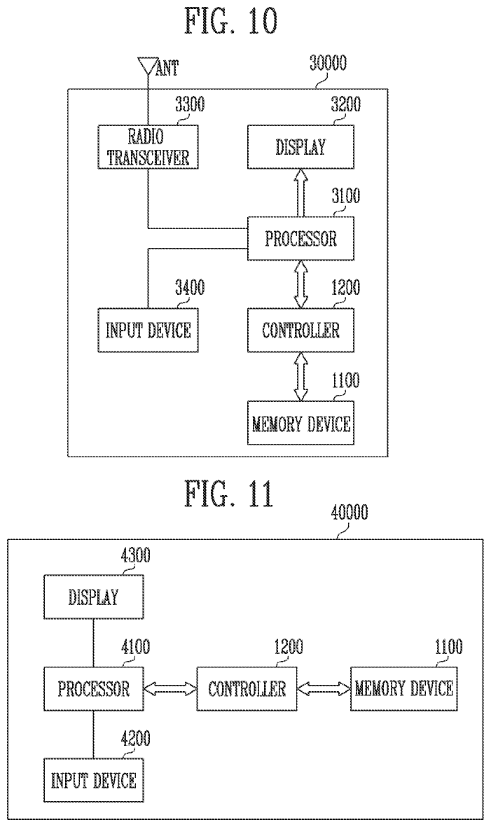

FIG. 10 is a diagram illustrating another embodiment of a memory system in accordance with the teachings of the present disclosure.

Referring to FIG. 10, a memory system 30000 may be implemented as a cellular phone, a smart phone, a tablet PC, a personal digital assistant (PDA), or a wireless communication device. The memory system 30000 may include a memory device 1100 and a controller 1200 capable of controlling an operation of the memory device 1100. The controller 1200 may control a data access operation of the memory device 1100, e.g., a program operation, an erase operation, a read operation, or the like under the control of a processor 3100.

Data programmed in the memory device 1100 may be output through a display 3200 under the control of the controller 1200.

The controller 1200 may organize a super block by using some memory blocks among a plurality of memory blocks included in the memory device 1100.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the controller 1200 or the display 3200. The controller 1200 may transmit the signal processed by the processor 3100 to the memory device 1100. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the controller 1200, data output from the radio transceiver 3300, or data output from the input device 3400 can be output through the display 3200.

In some embodiments, the controller 1200 capable of controlling an operation of the memory device 1100 may be implemented as a part of the processor 3100, or be implemented as a chip separate from the processor 3100. Also, the controller 1200 may be implemented as the controller 1200 shown in FIG. 2.

FIG. 11 is a diagram illustrating another embodiment of a memory system in accordance with the teachings of the present disclosure.

Referring to FIG. 11, a memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 1100 and a controller 1200 capable of controlling a data processing operation of the memory device 1100.

The controller 1200 may organize a super block by using some memory blocks among a plurality of memory blocks included in the memory device 1100.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the controller 1200. In some embodiments, the controller 1200 capable of controlling an operation of the memory device 1100 may be implemented as a part of the processor 4100, or be implemented as a chip separate from the processor 4100. Also, the controller 1200 may be implemented as the controller 1200 shown in FIG. 2.

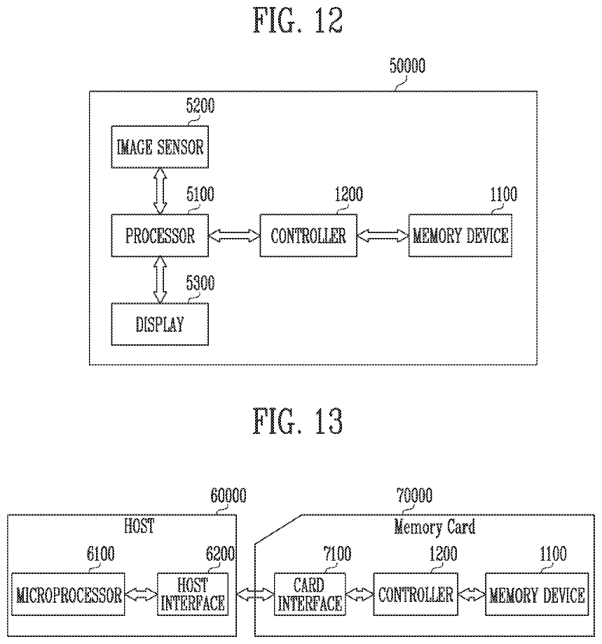

FIG. 12 is a diagram illustrating another embodiment of a memory system in accordance with the teachings of the present disclosure.

Referring to FIG. 12, a memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the controller 1200. Under the control of the processor 5100, the converted digital signals may be output through a display 5300, or be stored in the memory device 1100 through the controller 1200. In addition, data stored in the memory device 1100 may be output through the display 5300 under the control of the processor 5100 or the controller 1200.

The controller 1200 may organize a super block by using some memory blocks among a plurality of memory blocks included in the memory device 1100.

In some embodiments, the controller 1200 capable of controlling an operation of the memory device 1100 may be implemented as a part of the processor 5100, or be implemented as a chip separate from the processor 5100. Also, the controller 1200 may be implemented as the controller 1200 shown in FIG. 2.

FIG. 13 is a diagram illustrating another embodiment of a memory system in accordance with the teachings of the present disclosure.

Referring to FIG. 13, a memory system 70000 may be implemented as a memory card or a smart card. The memory system 70000 may include a memory device 1100, a controller 1200, and a card interface 7100.

The controller 1200 may organize a super block by using some memory blocks among a plurality of memory blocks included in the memory device 1100.

The controller 1200 may control data exchange between the memory device 1100 and the card interface 7100. In some embodiments, the card interface 7100 may be a secure digital (SD) card interface or a multi-media card (MMC) interface, but the present disclosure is not limited thereto. Also, the controller 1200 may be implemented as the controller 1200 shown in FIG. 2.

The card interface 7100 may interface data exchange between a host 60000 and the controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is coupled to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the controller 1200 under the control of a microprocessor 6100.

In accordance with the present disclosure, a retention characteristic of each of the plurality of semiconductor memories included in the memory device is determined, and a performance period of a garbage collection operation is set based on the determined retention characteristic, so that the reliability of data stored in the memory system can be improved. Further, a number of times a defense algorithm is performed in a read operation is decreased according to an optimized performance period of the garbage collection operation, so that read operation performance can be improved.

While the present disclosure has been shown and described with reference to certain embodiments thereof, it will be understood by those skilled in the art that various changes in form and detail may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or parts of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, some embodiments of the present disclosure have been described in the drawings and specification. Although specific terminologies are used here, those are only to explain the presented embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory system comprising:
a memory device including a plurality of semiconductor memories; and
a controller configured to set a performance period of a garbage collection operation of each of the plurality of semiconductor memories, based on a mobile ion amount of each of the plurality of semiconductor memories, and control the garbage collection operation of the plurality of semiconductor memories, based on the set performance period.

2. The memory system of claim 1,
wherein the controller includes a garbage collection controller for controlling the garbage collection operation of the plurality of semiconductor memories, and
wherein the garbage collection controller includes:
a mobile ion amount storage configured to store data about the mobile ion amount of each of the plurality of semiconductor memories; and
a period setting unit configured to set the performance period of each of the plurality of semiconductor memories, based on the data about the mobile ion amount, which is stored in the mobile ion amount storage.

3. The memory system of claim 2,
wherein each of the plurality of semiconductor memories includes a plurality of memory blocks, and
wherein at least one memory block among the plurality of memory blocks is allocated as a Content Addressable Memory (CAM) block for storing data about the mobile ion amount of a corresponding semiconductor memory.

4. The memory system of claim 3, wherein each of the plurality of semiconductor memories is configured to read the data about the mobile ion amount, which is stored in the CAM block, and transmit the read data to the controller in a booting operation.

5. The memory system of claim 4, wherein the mobile ion amount storage is configured to store the data about the mobile ion amount, which is received from the plurality of semiconductor memories in the booting operation.

6. The memory system of claim 2, wherein the garbage collection controller is configured to check a time since a last garbage collection operation of each of the plurality of semiconductor memories was performed.

7. The memory system of claim 6, wherein the garbage collection controller is configured to control the memory device to perform the garbage collection operation on a semiconductor memory for which the checked time reaches the performance period among the plurality of semiconductor memories.

8. The memory system of claim 1, wherein each of the plurality of semiconductor memories is configured to:
select at least one victim block among a plurality of memory blocks, read valid data stored in the victim block, and output the read valid data to the controller in the garbage collection operation; and
receive data to be programmed from the controller and store the received data in a target block among the plurality of memory blocks.

9. The memory system of claim 8,
wherein the controller includes an error corrector, and
wherein the error corrector is configured to perform an error correction operation on the valid data received from the memory device and generate the error-corrected valid data as the data to be programmed.

10. A method for operating a memory system comprising a memory device including a plurality of semiconductor memories and comprising a controller for controlling the memory device, the method comprising:
performing a program operation on each of the plurality of semiconductor memories;
performing a read operation on each of the plurality of semiconductor memories after the program operation is completed;
detecting and counting fail bits, based on a result of the read operation;
measuring a mobile ion amount of each of the plurality of semiconductor memories, based on the counted number of fail bits; and
storing information on the mobile ion amount of each of the plurality of semiconductor memories in a Content Addressable Memory (CAM) block of each of the plurality of semiconductor memories or the controller.

11. The method of claim 10, further comprising performing a stand-by operation for a set time before the read operation is performed and after the program operation is performed.

12. The method of claim 10, further comprising applying a set temperature to the memory device for a set time before the read operation is performed and after the program operation is performed.

13. The method of claim 10, wherein performing the program operation comprises programming random data or solid data.

14. The method of claim 10, wherein detecting and counting the fail bits comprises:
detecting a fail bit by comparing data programmed in the program operation and data read in the read operation with each other and determining the compared data is different; and
counting the detected fail bit.

15. The method of claim 14, wherein, in the measuring of the mobile ion amount of each of the plurality of semiconductor memories, the measured mobile ion amount increases as the counted fail bit number becomes larger.

16. A method for operating a memory system, the method comprising:
reading a mobile ion amount stored in a Content Addressable Memory (CAM) block included in each of a plurality of semiconductor memories and storing the read mobile ion amount in a garbage collection controller of a controller;
setting a performance period of a garbage collection operation of each of the plurality of semiconductor memories, based on the mobile ion amount of each of the plurality of semiconductor memories, which is stored in the garbage collection controller; and
performing the garbage collection operation of a semiconductor memory which reaches the performance period of the garbage collection operation among the plurality of semiconductor memories.

17. The method of claim 16, further comprising:
checking, after the setting the performance period, a time since a last garbage collection operation of each of the plurality of semiconductor memories was performed.

18. The method of claim 17, wherein performing the garbage collection operation includes:
detecting a semiconductor memory, of the plurality of semiconductor memories, for which the checked time reaches the performance period; and
performing the garbage collection operation on the detected semiconductor memory.

19. The method of claim 16, wherein performing the garbage collection operation comprises:
reading valid data stored in a selected victim block among a plurality of memory blocks included in the semiconductor memory and outputting the read valid data to the controller in the garbage collection operation;
performing an error correction operation on the read valid data; and
programming the valid data on which the error correction operation has been completed to a target block among the plurality of memory blocks.

20. The method of claim 19, further comprising erasing the victim block, after the target block has been completed programmed.
